(19) United States
(12) Patent Application Publication
(10) Pub. No.: US 2025/0108718 A1
(43) Pub. Date: Apr. 3, 2025

(54) CHARGING APPARATUS FOR AN ELECTRIC VEHICLE AND METHOD FOR CHARGING AN ELECTRIC VEHICLE

(71) Applicant: Siemens Aktiengesellschaft, Munchen (DE)

(72) Inventor: Jean-Mary Martel, Tegernheim (DE)

(21) Appl. No.: 18/901,205

(22) Filed: Sep. 30, 2024

(30) Foreign Application Priority Data
Sep. 28, 2023 (DE) 10 2023 209 506.8

(51) Int. Cl. B60L 53/62; B60L 53/16; B60L 53/22; H02J 7/00

(52) U.S. Cl. CPC B60L 53/62; B60L 53/16; B60L 53/22; H02J 7/0042; H02J 7/00712; H02J 2207/20

(57) ABSTRACT

A charging apparatus for electric vehicles includes a charging plug, power converter, current sensor between the power converter and the charging plug, switch and control unit. The power converter is connected to the charging plug and a supply connection, receives electrical energy from the supply connection and outputs it to the charging plug as required by the electric vehicle. The current sensor measures current flowing between the power converter and the charging plug and outputs it as a current measurement value. The switch switches off current flowing from the power converter to the charging plug. The control unit is connected to the current sensor and the switch and detects an electric arc event based on current measurement values and, upon detecting the event, controls the switch to switch off current flowing from the power converter to the charging plug. A method for charging an electric vehicle is also provided.

### CROSS-REFERENCE TO RELATED APPLICATION

This application claims the priority, under 35 U.S.C. § 119, of German Patent Application DE 10 2023 209 506.8, filed Sep. 28, 2023; the prior application is herewith incorporated by reference in its entirety.

### FIELD AND BACKGROUND OF THE INVENTION

The invention relates to a charging apparatus for an electric vehicle and to a method for charging an electric vehicle.

In the course of the desired decarbonization of motor vehicle traffic, motor vehicles are becoming increasingly electrified. Such electric vehicles have to be regularly charged by charging apparatuses. For that purpose, the electric vehicle is usually connected to the charging apparatus via a plug connection. A charging socket is disposed on the electric vehicle and is intended to receive a charging plug of the charging apparatus.

The charging apparatus is a power-electrical device. As a matter of principle, bodily harm and material damage should be avoided during operation and through the operation of the charging apparatus.

### SUMMARY OF THE INVENTION

It is accordingly an object of the invention to provide a charging apparatus for an electric vehicle and a method for charging an electric vehicle, which overcome the hereinafore-mentioned disadvantages of the heretofore-known apparatuses and methods of this general type and which introduce a safely operable charging apparatus and a safely operating method for a charging apparatus.

With the foregoing and other objects in view there is provided, in accordance with a first aspect of the invention, a charging apparatus for an electric vehicle. The charging apparatus comprises at least a charging plug, a power converter connected to the charging plug and to a supply connection of the charging apparatus, a current sensor connected between the power converter and the charging plug, a switch and a control unit. The charging plug is configured to be connected to the electric vehicle. The power converter is connected to the charging plug and to a supply connection of the charging apparatus and is configured to receive electrical energy from the supply connection and to output the electrical energy to the charging plug according to a requirement of the electric vehicle. The current sensor is connected between the power converter and the charging plug and is configured to measure a current flowing between the power converter and the charging plug and to output the current as a current measurement value. The switch is configured to switch off the current flowing from the power converter to the charging plug. The control unit is connected to the current sensor and to the switch. According to the invention, the control unit is configured to detect an electric arc event on the basis of a series of current measurement values and, upon detecting the electric arc event, to control the switch to switch off the current flowing from the power converter to the charging plug.

Preferred embodiments of the invention are specified in the dependent claims.

The invention is based on and incorporates the knowledge that an electric arc event at the plug connection between the charging plug and the electric vehicle can be detected on the basis of a series of current measurement values. Such an electric arc event may be caused by too loose a connection between the charging plug and the charging socket, which may in turn be attributed to deformations of the charging plug due to improper handling. The electric arc event leads to local heating, the resulting temperatures may lead to oxidation of the conductor surface at the location of the electric arc and, because of the thermal conduction of the metal of the conductor, also at surrounding insulators such as the cable sheath. Due to the oxidation, the electrical resistance increases, which in turn causes an increase in the thermal input due to a flowing current. What follows is a self-accelerating process which can ultimately lead to so much heat being generated that the charging plug, charging cable and electric vehicle spontaneously ignite. The charging apparatus of the invention can detect an electric arc event and, when such an electric arc event is present, effect a switching off of the charging current. Additionally, the charging apparatus can output a maintenance signal so that maintenance of the charging apparatus can be arranged for by a control center or the like, during which a damaged or undesirably strongly oxidized charging plug can be replaced or repaired, for example.

Particularly preferably, the control unit is configured to compare the current measurement values of the series of current measurement values with a current threshold value and to detect the electric arc event on the basis of a rate of instances of the current threshold value being exceeded and/or undershot. In this case, the current threshold value can be set in dependence on a power requirement of the electric vehicle. In particular for a DC charging process, the charging apparatus and electric vehicle negotiate the electrical parameters of the charging process so that a current threshold value can be derived therefrom, for example by setting the current threshold value to 90 percent of the expected charging current or another proportional value, wherein the current threshold value should be selected to be far enough below the expected charging current that a usual operational ripple of the charging current does not lead to a false detection due to internal switching processes of the power converter or else of the electric vehicle. The current threshold value can, however, also be adaptively derived from a moving average of the charging current or be selected according to previously known charging profiles.

Instances of exceedance and undershooting are understood herein to mean in particular crossings of charging current and current threshold value. An instance of the current threshold value being exceeded is then an event during which the charging current increases from below the current threshold value to above the current threshold value; an instance of undershooting is accordingly an event during which the charging current drops from above the current threshold value to below the current threshold value. Such events can occur occasionally due to switching processes and the like. In contrast, when an electric arc event is present, the flowing current exhibits constant, randomly acting fluctuations with a large fluctuation range which often occur several times per second. Accordingly, a high rate of instances of the current threshold value being exceeded and/or undershot can be used as a distinguishing feature of an electric arc event. In this case, the rate of instances of the current threshold value being exceeded and/or undershot is a criterion which is easy to determine and which is more meaningful than, for example, determining the periods of time or proportions of time during which the charging current is below or above the current threshold value.

In light of the highly dynamic behavior of the error pattern of the disruptive electric arc event, the current sensor is preferably configured to measure the charging current at least once per second, better still at least ten times per second or more.

An instance of exceedance may be recognized by the control unit in particular when a preceding current measurement value of the series of current measurement values is less than the current threshold value or equal to the current threshold value and a current measurement value immediately following the preceding current measurement value of the series of current measurement values is greater than the current threshold value. Accordingly, there may be an instance of undershooting in particular when a preceding current measurement value of the series of current measurement values is greater than the current threshold value or equal to the current threshold value and a current measurement value immediately following the preceding current measurement value of the series of current measurement values is less than the current threshold value. In terms of programming, this recognition can be implemented particularly easily in a microcontroller or the like.

The control unit is preferably configured to detect the electric arc event under a first condition, the first condition being met when the series of current measurement values has a first number of instances of the current threshold value being exceeded and/or undershot within a first period of time. For example, the first number can be selected to be between 20 and 80 instances of exceedance and/or undershooting, and the first period of time can be selected to be between 5 and 20 seconds.

The control unit in this case can furthermore be configured to detect the electric arc event under a second condition, the second condition being met when the series of current measurement values has a second number, different from the first number, of instances of the current threshold value being exceeded and/or undershot within a second period of time different from the first period of time. In this case, for example, the second number can be selected to be between 100 and 250 instances of exceedance and/or undershooting, and the second period of time can be selected to be between 20 and 100 seconds.

In this case, it is possible for the control unit to detect the electric arc event when only one of the two conditions is met, that is to say either the first condition or the second condition. This leads to particularly fast detection of the electric arc event. Alternatively, the control unit can also detect the electric arc event only when the first condition and the second condition are both met. In this case, false detections can be largely avoided.

In a particularly preferred embodiment of the charging apparatus according to the invention, the control unit can be configured to increment a counter when the current threshold value is exceeded and/or undershot and to decrement the counter after a predetermined period of time has elapsed. In this case, the control unit is configured to detect the electric arc event when the counter reaches a counter threshold value. This is a realization of the invention which is particularly easy to implement. In this case, the counter threshold value is only reached and the electric arc event detected when the rate of the instances of the current threshold value being exceeded and/or undershot over a relatively long period of time is above the rate of the decrementations of the counter due to the predetermined period of time repeatedly elapsing. This procedure establishes a “soft” criterion for the detection of an electric arc event. For example, the counter can be decremented by a value of 5 once per second and the counter threshold value can be selected to be 300. An electric arc event is detected when there are 350 instances of exceedance and/or undershooting within 10 seconds or 550 instances of exceedance and/or undershooting within 50 seconds, and so on.

The charging apparatus can be equipped with a filter connected between the current sensor and the control unit, the filter being configured to receive current measurement values from the current sensor, to filter the received current measurement values and to output the filtered current measurement values to the control unit. The filter can, for example, be a high-pass or band-pass filter which is passable within a frequency band typical for electric arc events. It is likewise conceivable to implement the filter as a Schmitt trigger with a switching hysteresis.

With the objects of the invention in view, there is concomitantly provided a second aspect of the invention which relates to a method for charging an electric vehicle, having the steps of:
measuring a charging current delivered to the electric vehicle in order to obtain a series of current measurement values;
detecting an electric arc event on the basis of the series of current measurement values; and
switching off the charging current when an electric arc event is detected.

The preferred embodiments described for the charging apparatus can be transferred directly to the method according to the invention, which will be briefly outlined below. In this case, the same considerations, developments, parameters, limit values, conditions and advantages as specified above for the charging apparatus apply.

In particularly preferred embodiments of the method according to the invention, an additional step of comparing the current measurement values of the series of current measurement values with a current threshold value and a step of detecting the electric arc event on the basis of a rate of instances of the current threshold value being exceeded and/or undershot are provided.

For example, an instance of exceedance may be detected when a preceding current measurement value of the series of current measurement values is less than the current threshold value or equal to the current threshold value and a current measurement value immediately following the preceding current measurement value of the series of current measurement values is greater than the current threshold value.

An instance of undershooting may be detected when a preceding current measurement value of the series of current measurement values is greater than the current threshold value or equal to the current threshold value and a current measurement value immediately following the preceding current measurement value of the series of current measurement values is less than the current threshold value.

The electric arc event may be detected under a first condition which may be met when the series of current measurement values has a first number of instances of the current threshold value being exceeded and/or undershot within a first period of time.

Additionally, a second condition for detecting the electric arc event may be provided, which second condition is met when the series of current measurement values has a second number, different from the first number, of instances of the current threshold value being exceeded and/or undershot within a second period of time different from the first period of time.

In this case, an additional prerequisite for detecting the electric arc event may be that the first condition and the second condition have to be met.

In particularly preferred implementations of the method according to the invention, a step of incrementing a counter when the current threshold value is exceeded and/or undershot and a step of decrementing the counter after a predetermined period of time has elapsed are provided. In this case, the electric arc event is detected when the counter reaches a counter threshold value.

Generally, provision can be made for current measurement values measured by the current sensor to undergo a step of filtering and for the filtered current measurement values to be used for the above-described steps of detecting the electric arc event. In the filtering step, a switching hysteresis may, for example, be applied to the measured current measurement values.

Other features which are considered as characteristic for the invention are set forth in the appended claims.

Although the invention is illustrated and described herein as embodied in a charging apparatus for an electric vehicle and a method for charging an electric vehicle, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a block diagram of an exemplary embodiment of a charging apparatus according to the invention;

FIG. 2 is a flow chart of an exemplary embodiment of a method according to the invention for charging an electric vehicle;

FIG. 3 is an exemplary transient diagram of the charging current I delivered to an electric vehicle, and

FIG. 4 is an exemplary transient diagram of a counter value as could be present when the method of FIG. 2 is implemented and when a charging current as in FIG. 3 occurs.

### DETAILED DESCRIPTION OF THE INVENTION

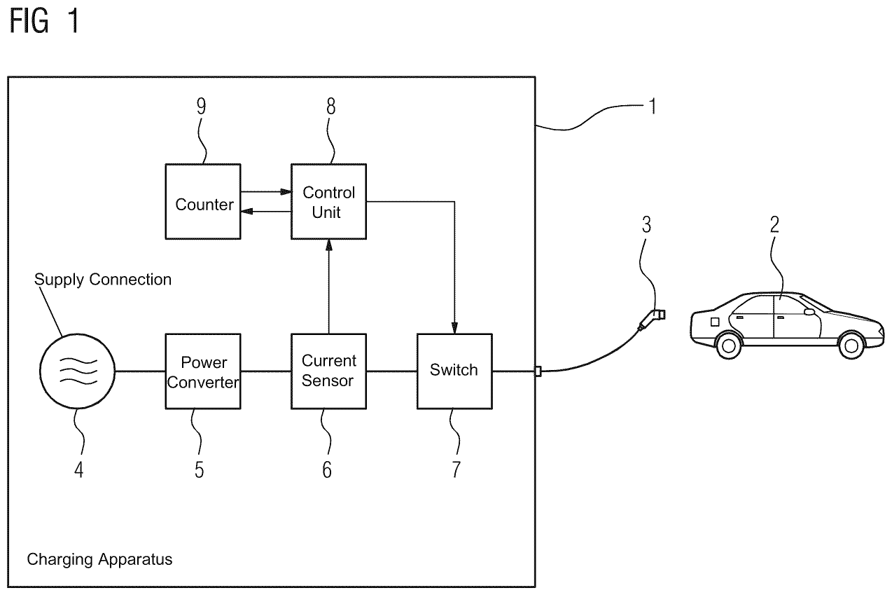

Referring now to the figures of the drawings in detail and first, particularly, to FIG. 1 thereof, there is seen an exemplary embodiment of a charging apparatus 1 according to the invention, wherein the charging apparatus 1 is illustrated in the form of a block diagram. The charging apparatus 1 can be connected to an electric vehicle 2 via a charging plug 3 and is itself supplied with power from a supply connection 4 which can, for example, be a three-phase low-voltage network connection. The charging apparatus 1 has a power converter 5 which is supplied with electrical energy via the supply connection 4 and produces a charging current that is suitable for charging the electric vehicle 2. The charging apparatus is preferably in the form of a DC charging apparatus to charge the electric vehicle 2 with a DC voltage or a DC current.

A current sensor 6 and a switch 7 are connected in series between the power converter 5 and the charging plug 3, wherein the switch 7 is connected downstream of the current sensor 6 in the present case. The current sensor 6 is connected to a control unit 8 which can receive and process current measurement values measured by the current sensor 6 and output to the control unit 8. The switch 7 can be controlled and opened or closed by the control unit 8. The switch is used to disconnect the charging plug 3 when an electric arc event is detected by the control unit 8 and when, as a result of the detection, the control unit 8 outputs to the switch a corresponding control signal to open the switch 7. The switch 7 can also be used during normal operation outside of charging processes to electrically disconnect the charging plug 3.

The control unit 8 is illustrated as being connected to a counter 9 but in most implementations of the charging apparatus 1 according to the invention the counter 9 will be implemented as part of the control unit 8 or as a variable of a control program. The counter 9 can be incremented or decremented by the control unit 8 during operation. In embodiments of the invention having the counter 9, its counter value is compared with a counter threshold value in order to decide whether an electric arc event is present or not.

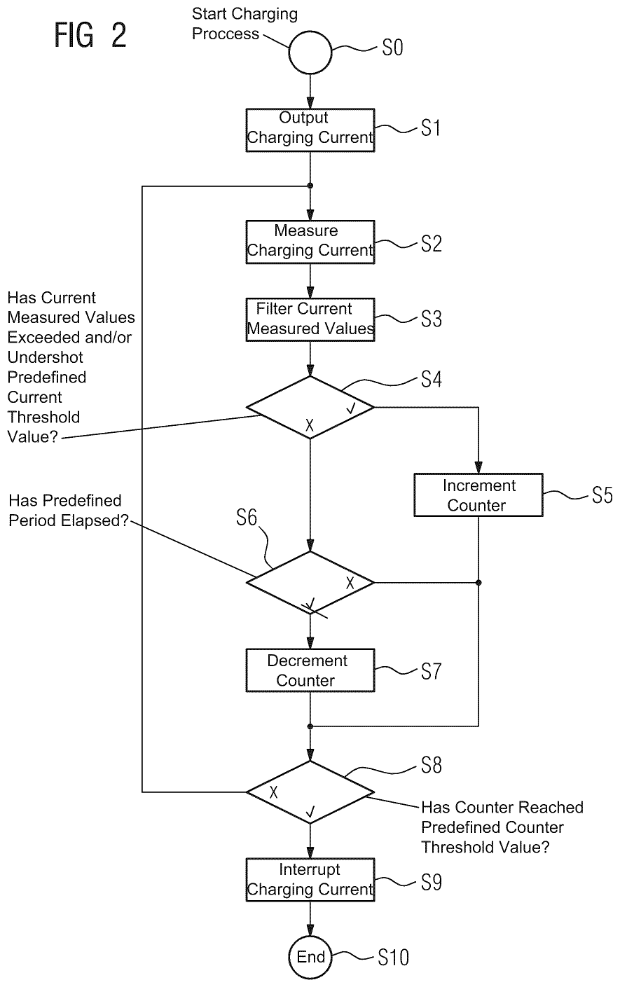

FIG. 2 shows an exemplary embodiment of a method according to the invention for charging an electric vehicle 2, which begins with a starting step S0 when a charging process for an electric vehicle 2 is begun. In a subsequent step S1, a charging current determined according to a requirement of the electric vehicle 2 is output. In step S2, the charging current that is output to the electric vehicle 2 is measured in order to obtain a series of current measurement values. The series of current measurement values is filtered in subsequent step S3, wherein various filter characteristics, optionally in combination with one another, can be used. The filtering is used to increase the reliability of the detection of an electric arc event but is optional. For example, the filtering can be provided in order to suppress harmonics and fluctuations of the charging current that are caused by switching processes of the power converter 5.

In step S4, it is checked whether the series of current measurement values has an instance of exceeding and/or undershooting a predefined current threshold value. An instance of exceedance is present, for example, when the current measurement values increase from below the current threshold value to above the current threshold value. In contrast, an instance of undershooting is present when the current measurement values decrease from above the current threshold value to below the current threshold value. The method can take into consideration both instances of exceedance and undershooting, or else also only one criterion of the two mentioned.

If it is determined in step S4 that an instance of exceedance or an instance of undershooting is present, the method branches to step S5 in which a counter is incremented. In contrast, if no instance of exceedance or undershooting is present, the method continues with step S6 in which it is checked whether a predefined period of time has elapsed, in particular has elapsed without an instance of exceedance or an instance of undershooting having been determined. If the check in step S6 gives a positive result, the counter is decremented in step S7, wherein the counter is preferably prevented from dropping into minus numbers should the counter have the counter value zero.

After the incrementation (step S5) or decrementation (step S7) of the counter, it is checked in step S8 whether the counter value has reached a predefined counter threshold value. If this is the case, the charging current has thus fluctuated in an unexpected and impermissible way and so the presence of an electric arc event is inferred. Thereupon, the charging current is interrupted in step S9, which brings about the protective function of the charging plug 3, of the charging socket of the electric vehicle 2, generally of the charging apparatus 1 and the surroundings, as desired according to the invention. In step S9, a fault signal can additionally be output or be output to a remote facility such as a remote maintenance center in order to indicate the need for maintenance work. The method according to the invention then ends in step S10. In contrast, if the check in step S8 reveals that the counter threshold value has not been reached, the charging process is continued and branched back to step S2 until the charging process is ended after the desired amount of energy has been delivered properly.

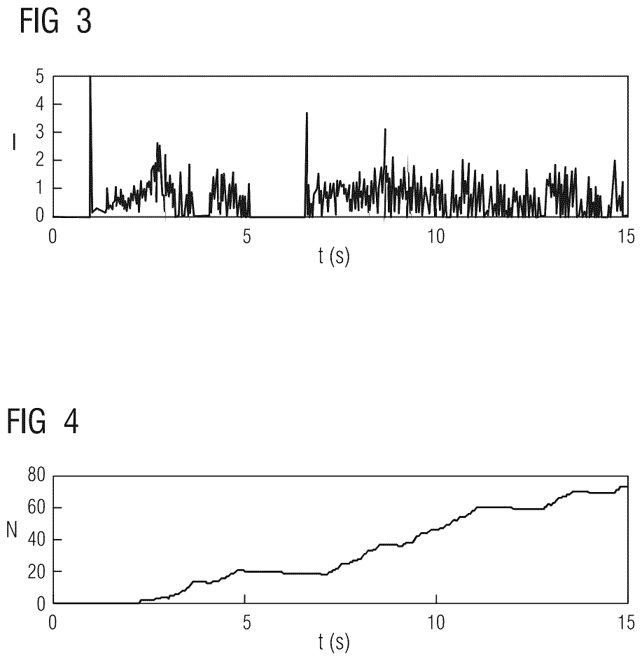

FIG. 3 shows an exemplary transient diagram of the charging current I delivered to an electric vehicle 2. In this case, the charging current I is plotted against time t, measured in seconds, and normalized in its size. Due to the presence of an electric arc event, the charging current I exhibits strong fluctuations and temporarily falls to zero, which indicates a temporary collapse of the electric arc between the charging plug 3 and the electric vehicle 2. Not illustrated, but likewise possible, are phases in which the charging current flows to the electric vehicle 2 undisrupted since there is for the moment sufficiently good contact between the charging plug 3 and the electric vehicle 2.

By virtue of the fact that the current measurement values are compared with a suitable current threshold value, an electric arc event can be detected in a reliable and simple manner. The shown charging current is normalized to the current threshold value in such a way that when the value 1 in the diagram is exceeded and/or undershot, the counter value is incremented as described above.

FIG. 4 shows an exemplary transient diagram of a counter value N as could be present when the method of FIG. 2 is implemented and when a charging current as in FIG. 3 occurs. The counter value N is again plotted against time t, wherein scaling corresponding to FIG. 3 has been selected. It appears that the counter value N increases over time due to the fluctuations in the charging current I and the consequently determined instances of the current threshold value being exceeded and/or undershot, wherein in phases in which the charging current I does not fluctuate (because it is interrupted or flowing undisrupted), the counter value slowly drops off again. The counter value increases over time, however, in such a way that if an electric arc continues to be present the counter threshold value is finally reached, and the charging current is interrupted as described above. In the example shown, a counter threshold value of 80 could be selected, for example, in such a way that the electric arc event is detected approximately at time t=18 seconds and the charging current is interrupted.

The invention has been explained in more detail with reference to representations of preferred exemplary embodiments but is not intended to be limited by them. Rather, the invention is defined solely by the following patent claims.

The following is a summary list of reference numerals, and the corresponding structure used in the above description of the invention:
1 Charging apparatus
2 Electric vehicle
3 Charging plug
4 Supply connection
5 Power converter
6 Current sensor
7 Switch
8 Control unit
9 Counter

1. A charging apparatus for an electric vehicle, the charging apparatus comprising:
a charging plug configured to be connected to the electric vehicle;
a supply connection of the charging apparatus;
a power converter connected to said charging plug and to said supply connection, said power converter configured to receive electrical energy from said supply connection and to output the electrical energy to said charging plug according to a requirement of the electric vehicle;
a current sensor connected between said power converter and said charging plug, said current sensor configured to measure a current flowing between said power converter and said charging plug and to output the current as a current measurement value;
a switch configured to switch off the current flowing from said power converter to said charging plug; and
a control unit connected to said sensor and to said switch, said control unit configured to detect an electric arc event based on a series of current measurement values and, upon detecting the electric arc event, to control said switch to switch off the current flowing from said power converter to said charging plug.

2. The charging apparatus according to claim 1, wherein said control unit is configured to compare current measurement values of the series of current measurement values with a current threshold value and to detect the electric arc event based on a rate of instances of the current threshold value being at least one of exceeded or undershot.

3. The charging apparatus according to claim 2, wherein an instance of exceedance exists when a preceding current measurement value of the series of current measurement values is less than the current threshold value or equal to the current threshold value and a current measurement value immediately following the preceding current measurement value of the series of current measurement values is greater than the current threshold value.

4. The charging apparatus according to claim 2, wherein an instance of undershooting exists when a preceding current measurement value of the series of current measurement values is greater than the current threshold value or equal to the current threshold value and a current measurement value immediately following the preceding current measurement value of the series of current measurement values is less than the current threshold value.

5. The charging apparatus according to claim 2, wherein said control unit is configured to detect the electric arc event under a first condition, the first condition being met when the series of current measurement values has a first number of instances of the current threshold value being at least one of exceeded or undershot within a first period of time.

6. The charging apparatus according to claim 5, wherein said control unit is furthermore configured to detect the electric arc event under a second condition, the second condition being met when the series of current measurement values has a second number, different from the first number, of instances of the current threshold value being at least one of exceeded or undershot within a second period of time different from the first period of time.

7. The charging apparatus according to claim 6, wherein said control unit is configured to only detect the electric arc event when the first condition and the second condition are met.

8. The charging apparatus according to claim 2, which further comprises a counter, said control unit configured to increment said counter when the current threshold value is at least one of exceeded or undershot and to decrement said counter after a predetermined period of time has elapsed, said control unit configured to detect the electric arc event when said counter reaches a counter threshold value.

9. The charging apparatus according to claim 2, which further comprises a filter connected between said current sensor and said control unit, said filter configured to receive current measurement values from said current sensor, to filter the received current measurement values and to output the filtered current measurement values to said control unit.

10. The charging apparatus according to claim 9, wherein said filter has a switching hysteresis.

11. A method for charging an electric vehicle, the method comprising:
measuring a charging current delivered to the electric vehicle in order to obtain a series of current measurement values;
detecting an electric arc event based on the series of current measurement values; and
switching off the charging current when an electric arc event is detected.
